(19) United States
(12) Patent Application Publication
(10) Pub. No.: US 2022/0052215 A1
(43) Pub. Date: Feb. 17, 2022

(54) CONCENTRATOR PHOTOVOLTAIC SYSTEM

(71) Applicant: QA-UK Ltd., Stanmore (GB)

(72) Inventors: Keith William John BARNHAM, Frome (GB); Barry Michael CLIVE, Richmond (GB)

(73) Assignee: QA-UK Ltd., Stanmore (GB)

(21) Appl. No.: 17/350,466

(22) Filed: Jun. 17, 2021

Related U.S. Application Data
(60) Provisional application No. 63/040,063, filed on Jun. 17, 2020.

(51) Int. Cl. H01L 31/054; H01L 31/0352

(52) U.S. Cl. CPC H01L 31/0543; H01L 31/035236; H01L 31/0547

(57) ABSTRACT

A photovoltaic solar concentrator comprising a non-tracking lens adapted to reach the limits of Etendue conservation for acceptance of a direct and a diffuse solar insolation and to emit a focused light onto an upper surface of a luminescent solar concentrator (LSC). The LSC comprises a crystal with an un-doped semiconductor with high luminescence efficiency in the form of a waveguide that includes a top-hat multi-layer reflector to reflect photo-luminescence within an escape cone of the crystal. A mirror attached to the bottom surface. Mirrors attached to all edges of the crystal except for one of the edges. A solar cell mounted on an un-mirrored edge, or optically connected to the un-mirrored edge of the crystal by a second waveguide, to receive the photo-luminescence trapped within the waveguide.

### RELATED APPLICATION/S

This application claims the benefit of priority of U.S. Provisional Patent Application No. 63/040,063 filed on Jun. 17, 2020, the contents of which are incorporated herein by reference in their entirety.

### BACKGROUND

The present disclosure, in some embodiments thereof, relates to a concentrator Photovoltaic (CPV) system and, more specifically, but not exclusively, to a concentrated photovoltaic cell for both direct and diffuse sunlight, based on a non-tracking lens and a luminescent solar concentrator (LSC). The non-tracking lens and a luminescent solar concentrator (LSC) can be incorporated in a solar panel, generate electricity with high power conversion efficiency. The non-tracking lens and a luminescent solar concentrator (LSC) can also produce one or more tuneable, narrow-band high intensity photon beams to illuminate a photo-electrochemical cell (PEC) or for many other applications.

### SUMMARY

The foregoing and other objects are achieved by the features of the independent claims. Further implementation forms are apparent from the dependent claims, the description and the figures.

A photovoltaic solar concentrator comprising a non-tracking lens adapted to reach the limits of Etendue conservation for acceptance of a direct and a diffuse solar insolation and to emit a focused light onto an upper surface of a luminescent solar concentrator (LSC). The LSC comprises a crystal with an un-doped semiconductor with high luminescence efficiency in the form of a waveguide that includes a top-hat, multi-layer reflector to reflect photo-luminescence within an escape cone of the crystal. A mirror attached to the bottom surface. Mirrors attached to all edges of the crystal except for one of the edges. A solar cell mounted on an un-mirrored edge, or optically connected to the un-mirrored edge of the crystal by a second waveguide, to receive the photo-luminescence trapped within the waveguide.

The luminescent solar concentrator may further comprise the crystal containing one or more quantum wells with high luminescence efficiency. A multi-quantum well solar cell may be mounted on the un-mirrored edge of the crystal, or optically connected to the un-mirrored edge of the crystal by a waveguide. Adjusting the composition, depth and width of the quantum wells in the multi-quantum well solar cell and the quantum well or wells in the luminescent concentrator so that the photo-luminescence will be resonantly absorbed by the multi-quantum well just above the absorption edge of a multi-quantum well cell.

The luminescent solar concentrator may further comprise an un-doped semiconductor crystal containing one or more quantum wells with high luminescence efficiency. A second waveguide (120) mounted on the un-mirrored edge of the crystal transmits the photo-luminescence to illuminate the catalyst in a photo-electrochemical cell.

The luminescent solar concentrator may further comprise an un-doped semiconductor crystal containing one or more quantum wells with high luminescence efficiency. A second waveguide mounted on the un-mirrored edge of the crystal transmits the photo-luminescence to illuminate the catalyst in a photo-electrochemical cell. The composition, width and depth of the quantum wells have been adjusted so as to resonantly illuminate the plasmonic absorption in metal nano-particle catalysts in the photo-electrochemical cell.

The luminescent solar concentrator may further comprise two un-doped semiconductor crystals containing one or more quantum wells with high luminescence efficiency arranged in tandem configuration. The top luminescent solar concentrator may absorb short-wavelength sunlight. The mirror attached to the bottom surface of a first luminescent solar concentrator (LSC) may be replaced by a multilayer, band-pass filter. The band pass filter reflects at the absorbed wavelengths, reflects the photo-luminescence from the quantum wells and transmits longer wavelength light to a second LSC. The first LSC may be coupled to the solar cell and be resonantly coupled to a multi-quantum well, coupled to a photo-electrochemical cell or resonantly coupled to the plasmon in a metal nanoparticle catalyst. The second LSC may be coupled to the solar cell, resonantly coupled to a multi-quantum well, coupled to a photo-electrochemical cell or resonantly coupled to the plasmon in a metal nanoparticle catalyst.

The first LSC may be replaced by one or more quantum dot concentrators or conventional high-band-gap solar cells. The conventional high-band-gap solar cells may be arranged in order of increasing wavelength of absorption edge towards the second LSC.

A photovoltaic solar concentrator, comprising a non-tracking lens adapted to reach the limits of Etendue conservation for acceptance of a direct and a diffuse solar insolation and to emit a focused light. A luminescent concentrator adapted to receive the focused light from the lens onto a top surface and through to a bottom surface of the luminescent concentrator. The luminescent concentrator is an un-doped semiconductor crystal. The top surface is opposite the bottom surface. The top and a bottom surfaces include at least two sides. At least two edges are common and perpendicular to the at least two sides. The surfaces of the at least two edges are mirrored. A top hat reflector adapted to reflect a photo-luminescence within an escape cone of the un-doped semiconductor crystal. A mirror attached to the bottom surface and a solar cell in the form of a waveguide. The waveguide is mounted or optically connected laterally to one un-mirrored edge of the at least two edges. The solar cell receives the photoluminescence (PL) trapped within the waveguide.

The luminescent concentrator may be a quantum well solar cell. The luminescent concentrator further comprises an un-doped semiconductor crystal adapted to contain one or more quantum wells with high luminescence efficiency. A multi-quantum well solar cell may be mounted to the one un-mirrored edge of the un-doped semiconductor crystal or optically connected to the waveguide. The one or more quantum wells are substantially identical in a composition, a depth and a width to the multi-quantum well solar cell to resonantly absorb at the absorption edge of a multi quantum wave (MQW) cell.

The luminescent concentrator may further comprise an un-doped semiconductor crystal containing one or more quantum wells with high luminescence efficiency. A second waveguide may be mounted opposite the waveguide. The second waveguide is adapted to transmit the photo-luminescence to illuminate a catalyst in a photo-electrochemical cell.

The luminescent concentrator may further comprise an un-doped semiconductor crystal. The semiconductor crystal contains one or more quantum wells with high luminescence efficiency. A second waveguide may be mounted to one un-mirrored edge of the un-doped semiconductor crystal. The second waveguide may be adapted to transmit the photo-luminescence to illuminate a catalyst in a photo-electrochemical cell, a composition, of a width and a depth of the quantum wells are adjustable to resonantly illuminate a plasmonic absorption in a metal nano-particle catalysts in the photo-electrochemical cell.

The concentrated photovoltaic cell of (CPC) including a structure, an array of the concentrated photovoltaic cells may be mounted to the structure. The structure may be mounted to a roof-top, to form a chimney flue. The chimney flue may be between the structure and the roof top and an airflow in the chimney flue cools the structure. A cooling system attached to the concentrated photovoltaic cell. The heat transfer between the temperatures of the concentrated photovoltaic cell to the cooling system provides a supply of heated water. A nanostructured filter located in the airflow of the chimney flue. The supply of heated water applied to the nanostructured filter, enables extraction of carbon dioxide and water vapor from the atmosphere in the vicinity of the structure.

The structure may be a roof of a building, wherein direct or indirect sunlight not focused by the non-tracking lens, goes through the luminescent concentrator, the non-tracking lens and an aperture in the roof to illuminate the interior of the building.

Unless otherwise defined, all technical and/or scientific terms used herein have the same meaning as commonly understood by one of ordinary skill in the art to which the disclosure pertains. Although methods and materials similar or equivalent to those described herein can be used in the practice or testing of embodiments of the disclosure, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE SEVERAL VIEWS OF THE DRAWINGS

Some embodiments of the disclosure are herein described, by way of example only, with reference to the accompanying drawings. With specific reference now to the drawings in detail, it is stressed that the particulars shown are by way of example and for purposes of illustrative discussion of embodiments of the disclosure. In this regard, the description taken with the drawings makes apparent to those skilled in the art how embodiments of the disclosure may be practiced.

In the drawings:

FIG. 1a is a is a cross sectional drawing of a concentrated photovoltaic cell (CPC), in accordance with some embodiments;

FIG. 1b is a is a drawing of a semiconductor band structure of an epitaxial layer shown in FIG. 1a, in accordance with some embodiments;

FIG. 2 is a cross sectional drawing of a concentrated photovoltaic cell (CPC), in accordance with some embodiments;

FIGS. 3a and 3b are respective plan drawings of a lens plate and a waveguide plate, in accordance with some embodiments;

FIG. 4a is a drawing of a solar panel, in accordance with some embodiments; and

FIG. 4b is a drawing of a concentrated photovoltaic cell (CPC) mounted to a roof-top of a building, in accordance with some embodiments.

### DETAILED DESCRIPTION

The present disclosure, in some embodiments thereof, relates to a concentrator Photovoltaic (CPV) system and, more specifically, but not exclusively, to a concentrated photovoltaic cell for both direct and diffuse sunlight, based on a non-tracking lens and a luminescent solar concentrator (LSC). The non-tracking lens and a luminescent solar concentrator (LSC) can be incorporated in a solar panel, generate electricity with high power conversion efficiency. The non-tracking lens and a luminescent solar concentrator (LSC) can also produce one or more tuneable, narrow-band high intensity photon beams to illuminate a photo-electrochemical cell (PEC) or for many other applications.

Before explaining at least one embodiment of the disclosure in detail, it is to be understood that the disclosure is not necessarily limited in its application to the details of construction and the arrangement of the components and/or methods set forth in the following description and/or illustrated in the drawings and/or the examples. The disclosure is capable of other embodiments or of being practiced or carried out in various ways.

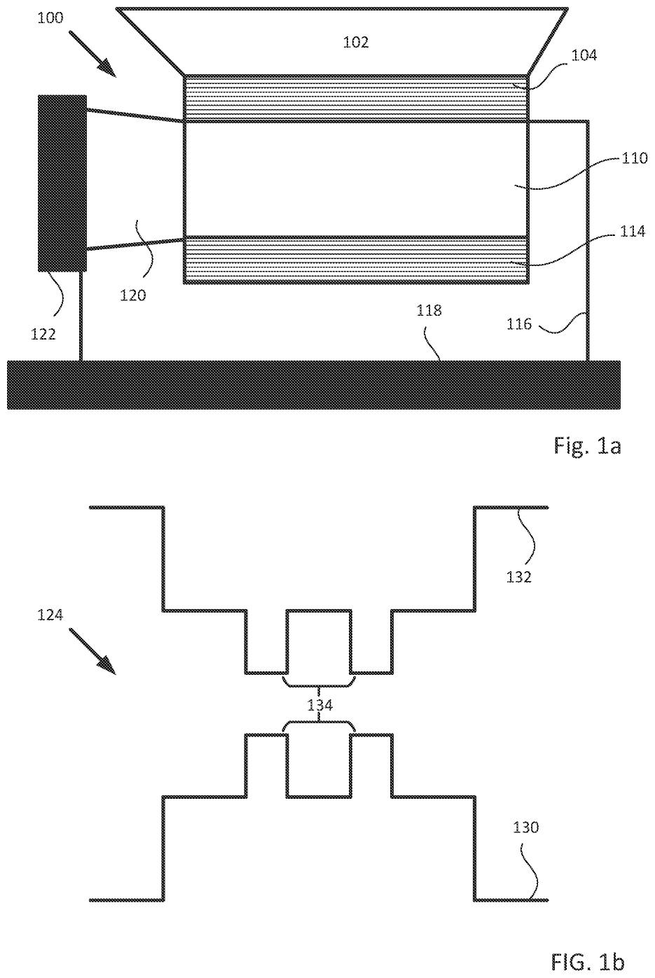

Reference is now made to FIG. 1a, which is a cross sectional drawing of a concentrated photovoltaic cell (CPC) 100, in accordance with some embodiments. Components of CPC 100 are fixed to be immovable and CPC 100 is immovably attached to a structure. Therefore, CPC 100 does not track light from the moving sun. The structure described in more details below may include a photovoltaic array, a green house, a solar chimney, a roof of a building or an atrium. A lens 102 is attached to a reflector 104. Lens 102 may have refractive index with high transmissivity to enable an acceptance of a direct and/or a diffuse solar insolation.

Luminescent solar concentrator (LSC) 110 is located between a top hat multilayer reflector 104 and mirror 114. Luminescent solar concentrator (LSC) 110 may be a Quantum Black Butterfly Luminescent Concentrator (QBBL). If a rectangle in shape with respect to a plan view (not shown), includes a top surface and a bottom surface of LSC 110 parallel to each other as shown in the cross sectional drawing. Four edges of LSC 110 are perpendicular to the respective four sides of the rectangle. In general, a shape of LSC 110 with respect to the plan view may be triangular, square or any polygon shape. The number of sides are with respect to number of edges. The number of edges being perpendicular to the respective number sides of the shape. Some of the edges of LSC 110 may be mirrored and other may not be mirrored.

Mounted to waveguide plate 116 and parallel with mirror 114 is solar cell 118. Solar cell 118 may be a copper indium gallium selenide solar cell (CIGS) or thermos-voltaic system.

Luminescent solar concentrator (LSC) 110 and mirror 114 are mounted on waveguide plate 116. Cell 122 may be mounted directly onto an un-mirrored edge of concentrator 124. Using the example of the rectangle shape the other three edges of LSC 110 may be mirrored to enable photoluminescence to be trapped in LSC 110. A waveguide 120 may be connected between cell 122 and LSC 110 as shown. Both waveguide 120 and cell 122 may be mounted to waveguide plate 116. Cell 122 may be a multi-quantum well solar cell or a photo-electrochemical cell.

Reference is also made to FIG. 1b, which is a drawing of a semiconductor band structure of Luminescent solar concentrator (LSC) 110 shown in FIG. 1a, in accordance with some embodiments. Where LSC 110 includes an un-doped two well, quantum black butterfly crystal (QBBC), the semiconductor band structure includes valence band 130 and conduction band 132 and two quantum wells 134.

During operation of concentrated photovoltaic cell (CPC) 100, phot-luminescence trapped in luminescent solar concentrator 110 may be reflected to cells 122. Where cell 122 is multi-quantum well solar cell, photo-luminescence from an escape cone of luminescent concentrator 110 illuminates quantum wells 134.

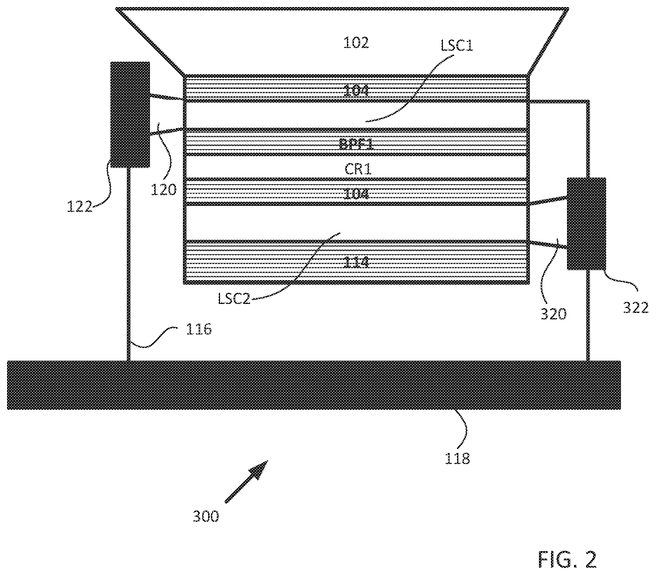

Reference is also made to FIG. 2, which is a cross sectional drawing of a concentrated photovoltaic cell (CPC) 300, in accordance with some embodiments. Components of CPC 300 are fixed to be immovable and CPC 300 is immovably attached to a structure. Therefore, CPC 300 does not track light from the moving sun. The structure described in more details below may include a photovoltaic array, a green house, a solar chimney, a roof of a building or an atrium. A lens 102 is attached to a reflector 104. Reflector 104 may be a top hat multi-layer reflector. Lens 102 may have a refractive index with high transmissivity to enable an acceptance of a direct and/or a diffuse solar insolation. Four edges of luminescent concentrators LSC1 and LSC2 are perpendicular to the respective four sides of the rectangle. In general, a shape of Luminescent Concentrators LSC1 and LSC2 with respect to the plan view may be triangular, square or any polygon shape. The number of sides are with respect to number of edges. The number of edges being perpendicular to the respective number sides of the shape. Some of the edges of Luminescent Concentrators LSC1 or LC2 may be mirrored and others may not be mirrored.

Cell 122 may be laterally attached directly to an un-mirrored edge of concentrator LSC1 or waveguide 120 may connect between cell 122 and the un-mirrored edge of luminescent concentrator LSC1. A band pass filter BPF1 may connect to the underside of luminescent concentrator LSC1. Cell 122 may be a multi-quantum well solar cell, quantum dot cell, or a photo-electrochemical cell. An air gap CR1 exist between band pass filter BPF1 and another reflector 104. Another concentrator LSC2 connects to the underside of the another reflector 104. Mirror 114 connects to the underside of concentrator LSC2. Mirror 114 may also be a long wavelength (λ) filter. Mounted to waveguide plate 116 and parallel with mirror 114 is solar cell 118. Solar cell 118 may be a copper indium gallium selenide solar cell (CIGS) or thermo-voltaic system. Cell 322 may be laterally attached directly to an un-mirrored edge of concentrator LSC2. Waveguide 320 may connect between cell 322 and the un-mirrored edge of luminescent concentrator LSC2. The un-mirrored edge of luminescent concentrator LSC2 may be opposite the un-mirrored edge of luminescent concentrator LSC1.

During operation of concentrated photovoltaic cell (CPC) 300, phot-luminescence trapped in both luminescent concentrators LSC1 and LSC2 may be reflected to respective cells 122 and 322. Where cell 122 is multi-quantum well solar cell, photo-luminescence from an escape cone of luminescent concentrator LSC1 illuminates quantum wells 134. Where cell 322 is a photo-electrochemical cell, photo-luminescence from an escape cone of luminescent concentrator LSC2 illuminates a catalyst in the photo-electrochemical cell.

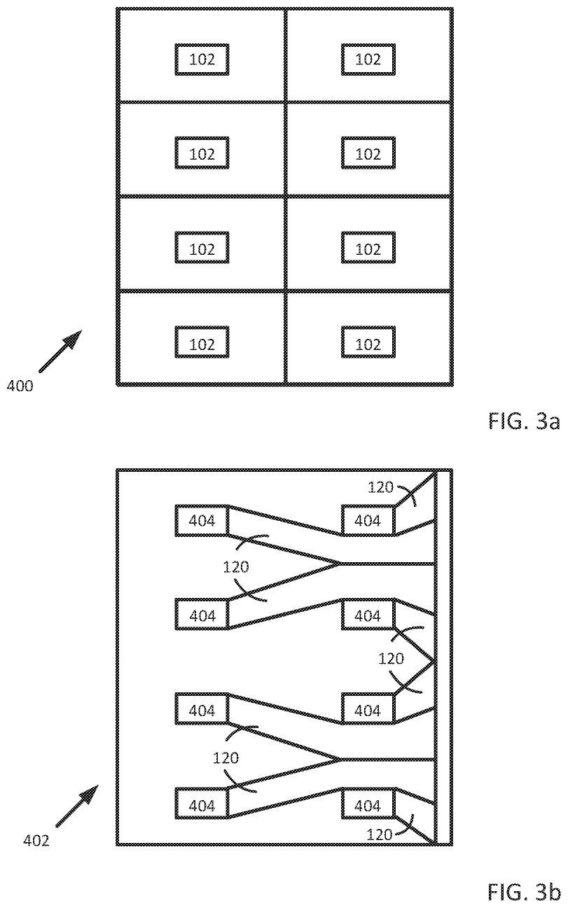

Reference is also made to FIG. 3a and FIG. 3b, which are respective plan drawings of a lens plate 400 and waveguide plate 402, in accordance with some embodiments. Lens plate 400 includes multiple lenses 102. Waveguide plate 402 shows multiple multi-quantum well (MQW) strain-balanced quantum well solar cells (SB-QWSC) 404 and multiple waveguides 120. Wave guide plate 402 is insert-able into lens plate 400 to form an array comparable in size with that of a standard silicon solar cell. The array can be connected in a two dimensional (2D) array in a roof-top solar panel.

### Generating Electrical Power

The main differences observable at the panel level will be:
1. The electrically active resonant SB-QWSC 404 concentrator cells, contacts and interconnects between the subunits of an array are protected by lenses 102 and lens plate 400.
2. The contacts at the edge of an array the size of a silicon cell will similarly be protected by lenses 102 and lens plate 400. The arrays forming a panel can abut and be sealed to protect the electrical interconnects between arrays. Hence, there are no electrical contacts on the top surface of the panel and no inactive regions of the panel. The sun-facing surface of lenses 102 can be protected in similar ways to the lenses in high-concentration tracking systems. There may be no need for a protecting sheet as in standard silicon panels.
3. The top surface of the array will be black, as it is an ideal black-body absorber for sunlight within the acceptance angles of lenses 102.
4. The power conversion efficiency of a panel formed from the array may be twice that of current top-performing silicon panels.
5. Higher power conversion efficiencies may be achieved if the luminescent solar concentrator (LSC) concentration reaches levels at which the recently discovered quantum butterfly effect (QBE) [Barnham et al., “The observation of thermal photon gain in quantum well solar cells”, Proceedings of the 46^{th} IEEE Photovoltaic Specialists Conference, Chicago, PVCS-2019-228, 18 Jun. 2019.] enhances output power and photon density.

### Single-Photon Photo-Electrochemistry

The resonant strain-balanced quantum well solar cells (SB-QWSC) 404 can be replaced by a photo-electrochemical cells (PEC) at the edge of cell 404, at the edge of an array of cells 404 or at the edge of the panel with waveguide interconnects between the unit cells 404. Instead of generating electric power the unit cell, array or panel can deliver one or more tuneable, high intensity, narrow-band photon beams to a catalyst on an electrode of the PEC. One application could be the photo-electrolysis of water to generate hydrogen. A thin-film cell can be used to bias the PEC. Sub-division of the thin-film cell, then re-connection in parallel and series, can bias the PEC cell to the threshold for water splitting, then the intense narrow band photons can enhance the reaction.

### Two Photon Photo-Electrochemistry

1. The tandem black butterfly luminescent concentrator (BBLC) of FIG. 2 for example, will deliver two or more tuneable, high-intensity, narrow-band photon beams onto a photo-electrochemical cell (PEC) on the edge of the unit cell or, with suitable waveguide interconnects, to a PEC on the edge of the panel.
2. One application of the two photon beams will be to illuminate catalysts on the electrodes of a PEC to produce solar fuels to replace diminishing fossil fuel reserves [Barnham, The Burning Answer: a User's Guide to the Solar Revolution, Weidenfeld and Nicolson, 2015. IBSN 987-17802-2533-3]. Of importance would be two-photon illumination of a catalyst on the photo-cathode of a PEC cell to selectively produce just one solar fuel, by reduction of atmospheric carbon dioxide. In doing so, the PEC effectively simulates what Nature already developed and demonstrates: chlorophyll uses photons from two narrow wavelength bands of sunlight to produce only carbohydrates from atmospheric carbon dioxide.
3. When photo-electrochemists find a catalyst that converts atmospheric carbon dioxide selectively to only one solar fuel with two carbon atoms per molecule, it is possible this could be a two- or three-photon process that could be driven by a black butterfly luminescent concentrator (BBLC). The wavelengths of the luminescent beams can adjust to match the catalyst. In addition to providing solar fuel, two-carbon-atom molecules could provide the feed-stock for the synthesis of higher order hydrocarbons by chemical processes for industrial applications.
4. The short wavelength cell of BBLC (QBBL 324 for example), produces a high-intensity photon beam that could excite a high density of energetic electrons in the metal nanoparticle (MNP) catalysts that are well known to reduce carbon dioxide to hydrocarbons by electrochemical means. With a very small change in quantum dot (QD) size the photo luminescence (PL) from the quantum dot luminescent concentrators 330a, 330b and 330c may be a near perfect match to the plasmonic absorption in the metal nanoparticles. A high density of energetic electrons necessary to reduce the carbon dioxide could be excited by one photon beam from the BBLC.
5. The complex hydrocarbons produced by the electrochemical reduction of carbon dioxide by metal nano particles (MNPs) are thought to result from two carbon dioxide molecules adhering to a metal nanoparticle facet that are fused by the ejection of a high energy electron from the metal catalyst. The wavelength of the photons from a second photon beam from the BBLC (QBBL 324 for example), could be adjusted to increase the electron density in the MNP so that the combined electron density reaches the critical value for electron emission at the fusion energy. A recent photo-electrochemical experiment [Sheng et al., “Carbon Dioxide Dimer Radical Anion as Surface Intermediate of Photoinduced CO₂ Reduction at Aqueous Cu and CdSe Nano Catalysts by Rapid-Scan FT-IR Spectroscopy”, Journal of the American Chemical Society, 140, 2018, 4363-4371], on copper nanoparticles has identified a dimer molecule that may be the precursor of two-carbon-atom reaction products in carbon dioxide reduction by photosynthesis.

In sum at this part of the description, a luminescent solar concentrator (LSC) is described above that is part of a novel non-tracking photovoltaic concentrator device. It is called the Quantum Black Butterfly (QBB) luminescent concentrator because it will act as a near-ideal black-body absorber and provide the high light concentrations at which to exploit the newly discovered phenomenon of Thermal Photon Gain (TPG) due to the Quantum Butterfly Effect (QBE).
1) The QBB will produce a tuneable, high intensity, narrow band photon beam from its quantum well (or quantum wells) that can resonantly illuminate a multi-quantum well (MQW) concentrator solar cell with identical quantum wells. It has been demonstrated [Hanifi et al., “Redefining near-unity luminescence with quantum dots in photothermal threshold quantum yield”, Science, 363, 1199-1202, 2019.], that resonant illumination of such a MQW cell by a laser results in power conversion efficiencies above 50%. A solar panel containing an interconnected array of Quantum Black Butterflies (QBBs) therefore has the potential to achieve double the power per unit area of the currently most efficient silicon cells.

Alternatively, the QBB can be configured to provide a tuneable, high intensity, narrow-band, photon beams to illuminate, for instance, a photo-electrochemical cell (PEC) to produce a solar fuel. If 2 QBBs are configured in a tandem arrangement in which the top QBB absorbs short-wavelength sunlight and allows long wavelength light into the lower QBB they will produce two tuneable, high-intensity, narrow-band photon beams to illuminate the catalyst in a PEC cell to produce a solar fuel. This would mimic nature. The chlorophyll in leaves uses solar photons in two narrow wavelength bands of sunlight to produce only carbohydrates from atmospheric carbon dioxide.

An alternative tandem configuration would see a Quantum Black Butterfly (QBB) as top cell illuminating a PEC cell to produce solar fuel while the QBB lower cell would produce power at around 20% efficiency from the long-wavelength half of the solar spectrum. For the same area of roof-top an array formed of a panel of such tandems would produce as much power for the building as current top-of-the range silicon panels, in addition to the solar fuel.

In any of these configurations the QBBs have the potential to achieve concentrations at which the thermal photon gain (TPG) due to the recently discovered Quantum Butterfly Effect will enhance output power and photon density.

In contrast to all previous luminescent solar concentrators based on plastics or glass waveguides doped with a luminescent species, the QBB is formed of an un-doped single semiconductor crystal with high luminescent efficiency.

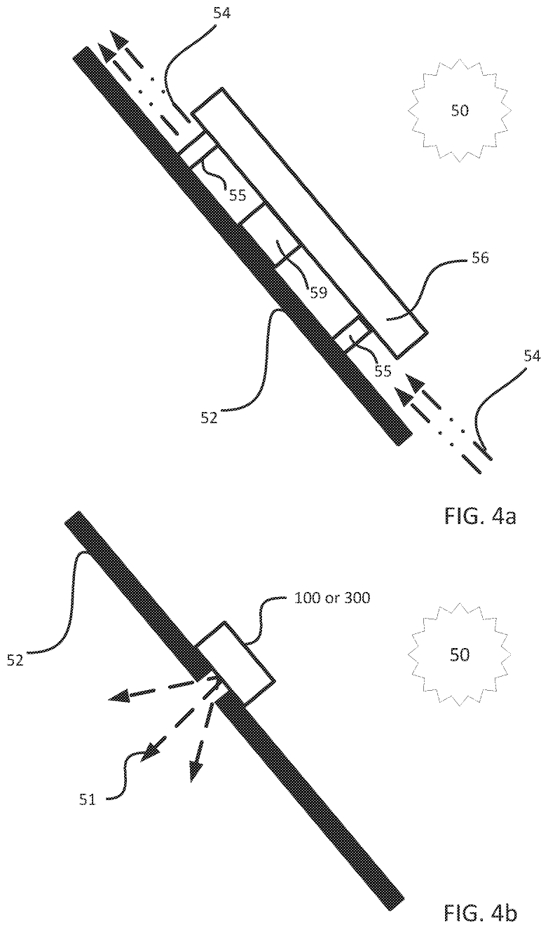

Reference is also made to FIG. 4a, which is a drawing of a solar panel, in accordance with some embodiments. Solar panel 56 is mounted on a roof-top 52 with mounts 55, a flue may be formed between solar panel 56 and roof-top 52 to act as a solar chimney. Sun 50 shines upon solar panel 56. An array of multiple concentrator cells in CPC 100 and/or CPC 300 may be located in solar panel 56. The solar chimney would provide airflow 54 to help cool the solar cells of solar panel 56 to allow the solar cells to operate more efficiently. Airflow 54 through an appropriate nanostructured filter 59 located in the flue of the chimney would extract carbon dioxide and water vapor from the atmosphere in the vicinity of solar panel 56. The water that cools the concentrator cells in CPC 100 and/or CPC 300 in solar panel 56 could provide heat to extract carbon dioxide and water from filter 59. Before a catalyst to convert carbon dioxide to a solar fuel is found, solar panel could produce up to twice the power per unit area of current silicon technology, while at the same time sequestering atmospheric carbon dioxide to help reduce global warming and providing a plentiful supply of distilled water in countries with high insolation.

Reference is also made to FIG. 4b, which is a drawing of a concentrated photovoltaic cell (CPC) 100 and/or CPC 300 mounted to a roof-top 52 of a building, in accordance with some embodiments. Direct or indirect sunlight from sun 50 not trapped in luminescent Concentrator (QBBL) 124, goes through concentrated photovoltaic cell (CPC) 100 and/or CPC 300. When (CPC) 100 and/or CPC 300 do not include solar cell 118 and aperture is mode in roof-top 52. The Direct or indirect sunlight from sun 50 not trapped in luminescent Concentrator (QBBL) 124, may illuminate the interior of the building.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

As used herein the term “about” refers to ±10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the disclosure may include a plurality of “optional” features unless such features conflict.

Throughout this application, various embodiments of this disclosure may be presented in a range format. It should be understood that the description in range format is merely for convenience and brevity and should not be construed as an inflexible limitation on the scope of the disclosure. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the disclosure, which are, for clarity, described in the context of separate embodiments, may also be provided in combination in a single embodiment. Conversely, various features of the disclosure, which are, for brevity, described in the context of a single embodiment, may also be provided separately or in any suitable sub-combination or as suitable in any other described embodiment of the disclosure. Certain features described in the context of various embodiments are not to be considered essential features of those embodiments, unless the embodiment is inoperative without those elements.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed:

1. A photovoltaic solar concentrator comprising:
a non-tracking lens adapted to reach the limits of Etendue conservation for acceptance of a direct and a diffuse solar insolation and to emit a focused light onto an upper surface of a luminescent solar concentrator (LSC), wherein the LSC comprises a crystal with an un-doped semiconductor with high luminescence efficiency in the form of a waveguide including:
a top-hat, multi-layer reflector to reflect photo-luminescence within an escape cone of the crystal;
a mirror attached to the bottom surface;
mirrors attached to all edges of the crystal except one; and
a solar cell mounted on an un-mirrored edge, or optically connected to the un-mirrored edge of the crystal by a second waveguide, to receive the photo-luminescence trapped within the waveguide.

2. The photovoltaic solar concentrator of claim 1, wherein the luminescent solar concentrator further comprises the crystal containing one or more quantum wells with high luminescence efficiency;
a multi-quantum well solar cell is mounted on the un-mirrored edge of the crystal, or optically connected to it by a waveguide;
adjusting the composition, depth and width of the quantum wells in the multi-quantum well solar cell and the quantum well or wells in the luminescent concentrator so that the photo-luminescence will be resonantly absorbed by the multi-quantum well just above the absorption edge of a multi-quantum well cell.

3. The photovoltaic solar concentrator of claim 1, wherein the luminescent solar concentrator further comprises an un-doped semiconductor crystal containing one or more quantum wells with high luminescence efficiency; and
a second waveguide (120) mounted on the un-mirrored edge of the crystal transmits the photo-luminescence to illuminate the catalyst in a photo-electrochemical cell.

4. The photovoltaic solar concentrator of claim 1, wherein the luminescent solar concentrator further comprises an un-doped semiconductor crystal containing one or more quantum wells with high luminescence efficiency;
a second waveguide mounted on the un-mirrored edge of the crystal transmits the photo-luminescence to illuminate the catalyst in a photo-electrochemical cell; and
the composition, width and depth of the quantum wells are adjustable so as to resonantly illuminate the plasmonic absorption in metal nano-particle catalysts in the photo-electrochemical cell.

5. The photovoltaic solar concentrator of claim 1, wherein the luminescent solar concentrator further comprises two un-doped semiconductor crystals containing one or more quantum wells with high luminescence efficiency arranged in tandem configuration;
the top luminescent solar concentrator absorbs short-wavelength sunlight;
the mirror attached to the bottom surface of a first luminescent solar concentrator (LSC) is replaced by a multilayer, band-pass filter that reflects at the absorbed wavelengths and reflects the photo-luminescence from the quantum wells and transmits longer wavelength light to a second LSC;
wherein the first LSC can be coupled to the solar cell as, resonantly coupled to a multi-quantum well, coupled to a photo-electrochemical cell or resonantly coupled to the plasmon in a metal nanoparticle catalyst; and
wherein the second LSC can be coupled to the solar cell, resonantly coupled to a multi-quantum well, coupled to a photo-electrochemical cell or resonantly coupled to the plasmon in a metal nanoparticle catalyst.

6. The photovoltaic solar concentrator of claim 5, wherein the first LSC can be replaced by one or more quantum dot concentrators or conventional high-band-gap solar cells arranged in order of increasing wavelength of absorption edge towards the second LSC.

7. The photovoltaic solar concentrator of claim 1, wherein the luminescent concentrator is a quantum well solar cell.

8. The photovoltaic solar concentrator of claim 1,
wherein the luminescent concentrator further comprises an un-doped semiconductor crystal adapted to contain one or more quantum wells with high luminescence efficiency,
wherein a multi-quantum well solar cell is mounted to the one un-mirrored edge of the un-doped semiconductor crystal or optically connected to the waveguide,
wherein the one or more quantum wells are substantially identical in a composition, a depth and a width to the multi-quantum well solar cell to resonantly absorb at the absorption edge of a multi quantum wave (MQW) cell.

9. The photovoltaic solar concentrator of claim 1, wherein the luminescent concentrator further comprises an un-doped semiconductor crystal containing one or more quantum wells with high luminescence efficiency, wherein a second waveguide is mounted opposite the waveguide, wherein the second waveguide is adapted to transmit the photo-luminescence to illuminate a catalyst in a photo-electrochemical cell.

10. The photovoltaic solar concentrator of claim 1, wherein the luminescent concentrator further comprises an un-doped semiconductor crystal, wherein the semiconductor crystal contains one or more quantum wells with high luminescence efficiency;
a second waveguide mounted to one un-mirrored edge of the un-doped semiconductor crystal, wherein the second waveguide is adapted to transmits the photo-luminescence to illuminate a catalyst in a photo-electrochemical cell,
wherein a composition, a width and a depth of the quantum wells are adjustable to resonantly illuminate a plasmonic absorption in a metal nano-particle catalysts in the photo-electrochemical cell.

11. The concentrated photovoltaic cell of (CPC) claim 1, further comprising:
a structure, wherein an array of the concentrated photovoltaic cells is mounted to the structure, wherein the structure is mounted to a roof top to form a chimney flue, wherein the chimney flue is between the structure and the roof top, wherein an airflow in the chimney flue cools the structure;
a cooling system attached to the concentrated photovoltaic cell, wherein the heat transfer between the temperature of the concentrated photovoltaic cell to the cooling system provides a supply of heated water; and
a nanostructured filter located in the airflow of the chimney flue, wherein the supply of heated water applied to the nanostructured filter, enables extraction of carbon dioxide and water vapor from the atmosphere in the vicinity of the structure.

12. The concentrated photovoltaic cell of claim 1, wherein the structure is a roof of a building, wherein direct or indirect sunlight not focused by the non-tracking lens, goes through the luminescent concentrator, the non-tracking lens and an aperture in the roof to illuminate the interior of the building.
